(19) United States
(12) Patent Application Publication
(10) Pub. No.: US 2026/0058646 A1
(43) Pub. Date: Feb. 26, 2026

(54) SOLID-STATE BIDIRECTIONAL SWITCH WITH SOFT SWITCHING

(71) Applicant: University of Connecticut, Farmington, CT (US)

(72) Inventors: Ali Bazzi, South Windsor, CT (US); Pengwei Li, Willington, CT (US); Matthew Silverman, West Hartford, CT (US)

(21) Appl. No.: 18/813,708

(22) Filed: Aug. 23, 2024

Related U.S. Application Data
(60) Provisional application No. 63/578,208, filed on Aug. 23, 2023.

(51) Int. Cl. H03K 17/0814; H03K 17/687; H03K 17/732

(52) U.S. Cl. CPC H03K 17/08142; H03K 17/6874; H03K 17/732

(57) ABSTRACT

An apparatus for controlling an electrical current flow between a first device and a second device includes a first semiconductor switch having a first conduction terminal and a second semiconductor switch having a first conduction terminal coupled to the first conduction terminal of the first semiconductor switch. The apparatus also includes a first snubber circuit coupled to a second conduction terminal of the first semiconductor switch and a second snubber circuit coupled to a second conduction terminal of the second semiconductor switch, wherein the first snubber circuit is adapted to couple with the first device and the second snubber circuit is adapted to couple with the second device.

### BACKGROUND OF THE INVENTION

### 1. Field of the Invention

The invention disclosed herein relates to power electronics, and in particular to solid-state bidirectional switching.

### 2. Description of the Related Art

Electromechanical relays have been used in the past in a wide-variety of power control and electrical applications. These mechanical devices, which are generally constructed with a coil and contacts, have demonstrated considerable reliability although they suffer from problems associated with having moving parts. In addition, mechanical relays are subject to arcing and sparking. In applications, where it is required to switch a high DC voltage, the cost of a mechanical relay grows very rapidly. Also, the switching of the coil leads to voltage spikes (a fly-back voltage.) A lot of power is required to control the coil, and in high power relays, the coil can consume tens of watts. Material fatigue can shorten the life of a mechanical relay, and reliability can suffer due to shock and vibration.

These types of mechanical issues are major concerns when the relay is used in harsh environments. For example, many vehicles, such as submarines, cars, tractor/trailers, heavy vehicles and aircraft use a wide variety of relays in their systems. These relays are subject to constant vibrations introduced by the operation of the vehicles. Furthermore, many times relays built with mechanical contacts are exposed to environmental substances that are corrosive (liquid gases and the like) that lead to breakdown.

In addition to mechanical problems, electromechanical relays create abrupt “on” and “off” transitions thus introducing large transitional spikes. Quite often, a large current surge will weld contacts creating undesirable “shorted-on” malfunctions. In addition, sparking caused by connecting and disconnecting contacts can ignite surrounding gases and start fires.

Nowadays, some power devices are built with internal protection using a field-effect transistor with an integrated current and temperature sensing. This allows building a self-protective power device when there are only low-voltage field-effect transistors available. Some designs place a small-value resistor inserted in series with the load to measure a bypass current. This helps in some cases, but the extra generated heat makes that method unpopular. In addition, a current sense resistor adds to the overall resistance of the channel and thus reduces the efficiency of the device.

One attempt to solve these problems is provided in U.S. Pat. No. 7,304,828. Unfortunately, the back-to-back MOSFET gate unification control method disclosed therein does not enable effective operation in application scenarios where users need current flow to be individually controllable. In this technology, it is not possible to limit current return in the event of a short circuit on one side of the power line, which can cause damage to higher level devices. Due to the parasitic inductance and parasitic capacitance parameters in the power line, conventional solid-state relays have transient current and voltage shocks at the moment of turn-on and turn-off. Voltage shocks are highly likely to cause permanent insulation damage to semiconductor devices, and current shocks cause junction temperatures of field-effect tubes to exceed safe temperatures in a short period of time. These shocks make it impossible for conventional schemes to ensure reliable operation of solid-state relays in medium to high power level scenarios.

Thus, what are needed are methods and apparatus to provide solid-state switching capabilities that are separately controllable under a variety of operational conditions.

### SUMMARY OF THE INVENTION

Provided herein are embodiments of solid-state relays that can be freely switched between four different operating states by independent or joint control of dual channel control signals. This allows a higher degree of freedom for the control and protection of power line currents than is presently available. For the different control/protection needs of AC/DC systems, this solid-state relay greatly increases the applicability and flexibility of the scenario.

Disclosed is an apparatus for controlling an electrical current flow between a first device and a second device. The apparatus includes a first semiconductor switch comprising a first conduction terminal and a second semiconductor switch comprising a first conduction terminal coupled to the first conduction terminal of the first semiconductor switch. The apparatus also includes a first snubber circuit coupled to a second conduction terminal of the first semiconductor switch and a second snubber circuit coupled to a second conduction terminal of the second semiconductor switch, wherein the first snubber circuit is adapted to couple with the first device and the second snubber circuit is adapted to couple with the second device.

Also disclosed is an apparatus includes a first semiconductor switch having a first conduction terminal and a second semiconductor switch having a first conduction terminal coupled to the first conduction terminal of the first semiconductor switch. The apparatus also includes a first snubber circuit coupled to a second conduction terminal of the first semiconductor switch and a second snubber circuit coupled to a second conduction terminal of the second semiconductor switch. The apparatus further includes a first device coupled to an output terminal of the first snubber circuit and a second device coupled to an output terminal of the second snubber circuit.

Further disclosed is a non-transitory computer-readable medium comprising instructions for controlling an electrical current flow between a first device and a second device that when executed by a computer implements a method. The method includes operating a bidirectional controllable solid-state relay, the bidirectional controllable relay comprising: a first semiconductor switch having a first conduction terminal; a second semiconductor switch having a first conduction terminal coupled to the first conduction terminal of the first semiconductor switch; a first snubber circuit coupled to a second conduction terminal of the first semiconductor switch; a second snubber circuit coupled to a second conduction terminal of the second semiconductor switch; wherein the first device is coupled to an output terminal of the first snubber circuit and the second device is coupled to an output terminal of the second snubber circuit. The method also includes (i) turning on the first semiconductor switch in response to the instructions allowing the electrical current flow from the first device to the second device; (ii) turning on the second semiconductor switch in response to the instructions allowing the electrical current flow from the second device to the first device; and (iii) turning on the first semiconductor switch and the second semiconductor switch in response to the instructions allowing the electrical current flow from the first device to the second device and from the second device to the first device.

### BRIEF DESCRIPTION OF THE DRAWINGS

The features and advantages of the invention are apparent from the following description taken in conjunction with the accompanying drawings in which:

FIG. 1 is a logic diagram depicting various states electrical current flow for the bidirectional solid-state relays according to the teachings herein;

FIG. 2 depicts aspects of soft switching in the bidirectional solid-state relays;

FIG. 3 depicts aspects of a control and drive circuit for the bidirectional solid-state relays according to the teachings herein;

FIG. 4 depicts aspects of a surge-free circuit the solid-state relays according to the teachings herein;

FIGS. 5A and 5B, collectively referred to herein as FIG. 5, are graphics depicting surge free switching for the circuit of FIG. 4;

FIG. 6 depicts aspects of an embodiment of the circuits according to the teachings herein;

FIG. 7 is a schematic diagram for an embodiment of the circuits according to the teachings herein;

FIG. 8 is the schematic diagram of FIG. 7 with the addition of boxes surrounding certain circuits for identification purposes;

FIG. 9 is a contrast diagram for an embodiment of the circuits according to the teachings herein;

FIGS. 10A and 10B, collectively referred to herein as FIG. 10, are top-side (FIG. 10A) and bottom-side (FIG. 10B) diagrams for the circuits of FIGS. 7, 8, and 9;

FIG. 11 is a flow chart for a method for controlling an electrical current flow between an electrical source and an electrical receiver;

FIG. 12 depicts aspects of a vehicle having the bidirectional solid-state relay;

FIG. 13 depicts aspects of a solar panel system having the bidirectional solid-state relay; and

FIG. 14 depicts aspects of a programmable logic controller system having the bidirectional solid-state relay.

### DETAILED DESCRIPTION OF THE INVENTION

Disclosed herein are methods and apparatus for controlling switching of solid-state relays (SSR). Advantageously, the technology provides an active soft-switching buffer circuit to effectively suppress transient shocks such as current and voltage shocks as may be caused by parasitic energy storage elements in solid-state relays in medium and high-power applications.

In some of the embodiments provided, zero-current turn-on and zero-voltage turn-off of a solid-state relay are achieved. This effectively improves the reliability of the solid-state relay. Compared with traditional electromagnetic relays, the circuit has low losses, fast response time, and no contact damage problems due to arc scorching. In addition, the solid-state relay has the advantage of stable parameters, and the product is subject to low assembly and production accuracy requirements. Thus, the stability and reliability of the relay is technically improved.

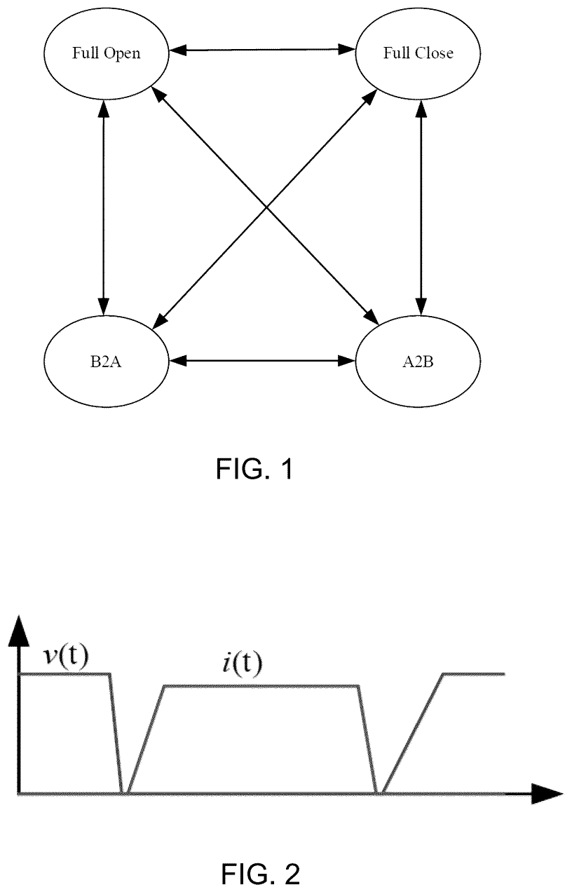

FIG. 1 illustrates the overall concept of directed electrical current flow for the solid-state bidirectional relays having output terminal A and output terminal B. As illustrated in FIG. 1, there are four possible states: (1) Full Open where current can flow from A to B and from B to A; (2) Full Closed where current cannot flow A to B and from B to A; (3) B2A where current can only flow from B to A and not from A to B; and (4) A2B where current can only flow from A to B and not from B to A. As can be seen any one state can be reached directly from any other state.

FIG. 2 illustrate voltage and current curves over time that depict aspects of the soft switching for the sold-state bidirectional relays. FIG. 2 illustrates voltage and current characteristics for turn-on and turn off modes of the sold-state bidirectional relays. The slopes of the voltage and current over time for turn-on and turn off modes suppress transient shocks caused by parasitic energy storage elements. In addition, the curves illustrate zero-current at turn-on and zero-voltage at turn-off to eliminate circuit losses.

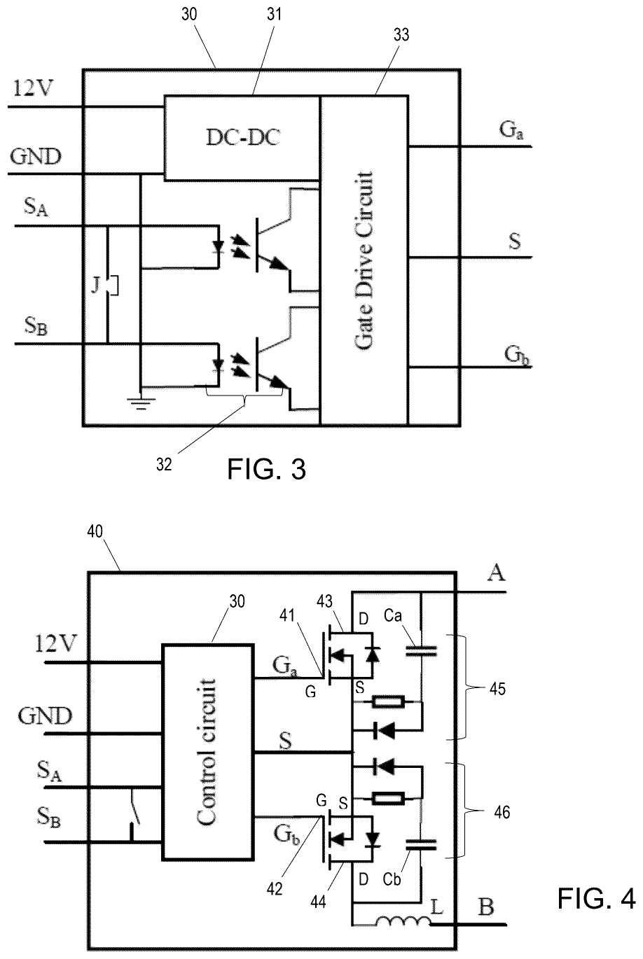

In one example illustrated in FIG. 3, a bidirectional controllable solid-state relay includes a control and drive circuit 30. The control and drive circuit 30 includes a DC-DC isolated power supply module 31 (e.g., TME1215), a high speed optocoupler signal isolator 32 (e.g., HCPL0630) and a push-pull output gate driver circuit 33. Output of the control and drive circuit 30 includes gate and drive signals Ga and Gb that are used to drive separate metal-oxide-semiconductor-field-effect-transistors (MOSFETs) and reference signal S. In an independent control application scenario, the jumpers J, SA and SB (shown disconnected) independently control the output of the gate drive signals Ga and Gb, thus allowing independent turn-on and turn-off control of the MOSFETs in a back-to-back configuration. The DC-DC isolated power supply module 31 is a boost converter used to power the gate drive circuit. This is a specific implementation for a 12V input to power the gate driver, and other and other circuit may not require the boost converter.

A resistor-capacitor-diode (RCD) absorber circuit also referred to as a snubber circuit absorbs the magnetic field energy from the power line parasitic inductor and the series inductor L during the turn-off transient.

FIG. 4 is a high-level schematic circuit diagram of a bidirectional controllable solid-state relay 40 having conduction terminals A and B. In the example depicted in FIG. 4, a terminal 41 for conducting the gate drive signal Ga is connected to a MOSFET 43 while a terminal 42 for conducting the gate drive signal Gb is connected to a MOSFET 44. Each MOSFET includes a gate terminal (G), a drain terminal (D), and a source terminal (S). In the embodiment of FIG. 4, the source terminals S of each MOSFET are coupled together in a back-to-back configuration. In FIG. 4, aspects of operation principles for the circuit are shown. The solid-state relay 40 includes a snubber circuit 45 coupled to the drain of the MOSFET 43 and another snubber circuit 46 coupled to the drain of the MOSFET 44. The snubber circuits 45 and 46 are configured to implement smooth-switching as described below. A capacitor Ca is connected to an output of the MOSFET 43, while a capacitor Cb is connected to an output of the MOSFET 44. Considering a turn-on transient, before connection, the energy in capacitors Ca and Cb is:

$$\{ \begin{matrix}{E}_{a} = \frac{1}{2} {C}_{a} {V}_{a}^{2} \\ {E}_{b} = \frac{1}{2} {C}_{b} {V}_{b}^{2}\end{matrix}$$

where Ca and Cb are the capacitance of and Va and Vb are the voltage across capacitors Ca and Cb, respectively, and the energy difference between the two capacitors is:

$$Δ E = \vert {E}_{a} - {E}_{b} \vert = \frac{1}{2} \vert {C}_{a} {V}_{a}^{2} - {C}_{b} {V}_{b}^{2} \vert$$

In a transient process, the inductor and capacitor will exchange energy during several resonate periods. The maximum inductor energy exists when Vₐ equals V_{b}. That is:

$${\sum }_{L}^{max} - Δ E$$

where E_{L} is the maximum energy in the inductor in the transient process. That is, E_{L} is the instant energy in the inductor and its maximum value equals ΔE. According to the inductor energy, the inductor value can be determined by:

$$L = \frac{\vert {C}_{a} {V}_{a}^{2} - {C}_{b} {V}_{b}^{2} \vert}{{( {i}_{L}^{max} )}^{2}}$$

where i_{L}^{max} is the maximum current in the inductor having inductance L. Furthermore, the RCD absorber circuit or snubber circuit can be designed by the inductor energy: in steady state, the bidirectional relay 40 is transmitting the current from one power source to a load in an embodiment, and the current is Iₛ. The energy in the inductor is:

$$\{ \begin{matrix}{E}_{L}^{s} = \frac{1}{2} {LI}_{s}^{2} \\ {E}_{snb}^{max} = \frac{1}{2} {C}_{s} {V}_{snb}^{2}\end{matrix}$$

where Cₛ is the snubber capacitor (Ca or Cb) and V_{snb} is the voltage across the snubber capacitor.

The snubber capacitor (Ca or Cb) shall take the same amount of energy as inductor current decreased to zero. In this way, the snubber capacitor value C_{snb} can be determined as:

$${C}_{snb} = \frac{{LI}_{s}^{2}}{{V}_{snb}^{2}}$$

During turn-on process, the current rising in the inductor satisfies the equation:

$$\{ \begin{matrix}( L + {L}_{p} ) \frac{{di}_{L}}{dt} = Δ υ \\ Δ υ = Δ {V}_{0} - \frac{1}{{C}_{a}} \int {i}_{L} dt - \frac{1}{{C}_{b}} \int {i}_{L} dt\end{matrix}$$

It can be simplified into:

$$\{ \begin{matrix}( L + {L}_{p} ) \frac{{di}_{L}}{dt} = Δ υ \\ \frac{{C}_{a} {C}_{b}}{{C}_{a} + {C}_{b}} \frac{d Δ υ}{dt} = - {i}_{L}\end{matrix}$$

where the Lₚ is the parasitic inductor in power line. To eliminate the oscillation of the second order system, if the initial voltage V_{ab} across terminals A and B is positive, the control signal can only turn on the MOSFET A (i.e., MOSFET 43). The current can only pass through one direction. After the oscillation process is completed, the two MOSFETs 43 and 44 are turned on to perform the bidirectional current flow. If the initial difference voltage V_{ab} is negative, the operation process shall be inversed for that case.

The resistors Ra and Rb in the snubber circuits can be selected to minimize the power loss in disconnection mode for a specified time constant value with the associated snubber capacitor.

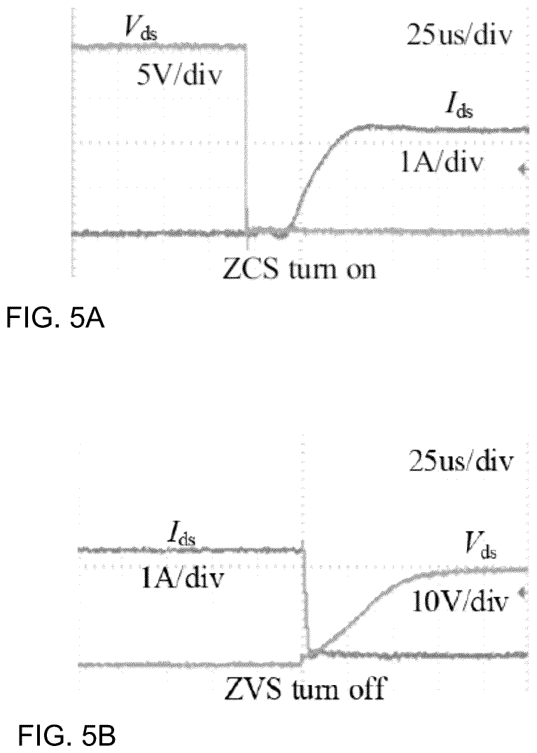

FIGS. 5A and 5B are graphics depicting surge free switching for the circuit of FIG. 4. In FIG. 5, ZCS is zero current switching, ZVS is zero voltage switching, Vds is voltage between drain and source, and Ids is current through drain to source. FIG. 5A shows the transient of a close operation of the solid-state relay, where the drain-source voltage is dropped due to the turning on of the relay and the current through the relay is increased. It shows that the current increased after the voltage drop and that can reduce the switching loss and current spike completely. FIG. 5B show s the open circuit operation of the solid-state relay. Both of these two transients show the designed solid-state relay can be operated without any voltage and current overshoot.

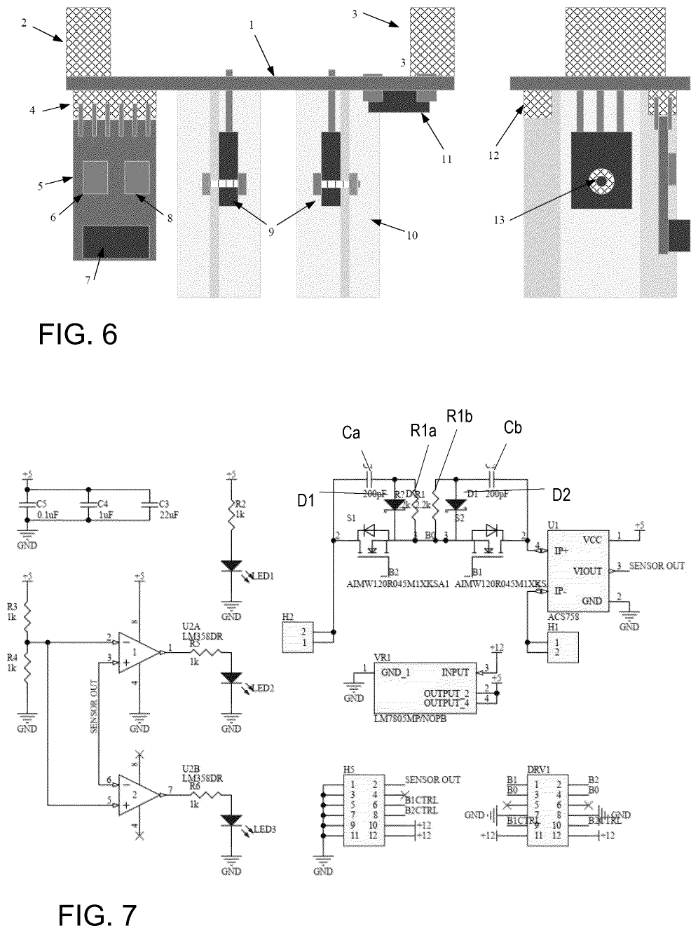

Referring to FIG. 6, an example of a layout of components for a circuit of the bidirectional controllable solid-state relay 40 is shown. In this example, the following nomenclature applies: 1 represents the main board of solid-state relay 40; 2 is terminal A connector; 3 is terminal B connector; 4 is control and drive module interface; 5 is drive module; 6 is signal isolation integrated circuit (IC); 7 is a DC-DC module; 8 is a drive IC; 9 is a SiC MOSFET (43 and 44 in FIG. 4); 10 is a heatsink; 11 is a current sensor; 12 is a control interface and 13 represents install bolts.

FIG. 7 is a schematic diagram for an embodiment of various sub-circuits making up an overall circuit of the bidirectional controllable solid-state relay 40. The sub-circuits are interconnected but shown as separated for clarity.

An example of a listing of a build of materials for the various sub-circuits shown in FIG. 7 is provided in Table 1.

TABLE 1
Build of Materials

| | | | | |
|---|---|---|---|---|
| Capacitor | C1, C2, C3, | 1206 | Cap | 5 |
| | C4, C5 | | | |
| FFP15S60S | D1, D2 | TO-220-2 | Schottky Diode | 2 |
| Header, | DRV1, H5 | 2.54mmx2 | Header 6X2 | 2 |
| Header | H1, H2 | DIP2_9.5 | Header 2 | 2 |
| LED, | LED1, 2, 3 | 0805 | LED2 | 3 |
| Resistor | R1-7 | 0805 | Res3 | 7 |
| 6399BG | S1, S2 | Bolt On | Heatsink | 2 |
| AIMW120R045M1 | S1, S2 | TO-247 | SiC MOSFET | 2 |
| ACS758 | U1 | XDCR_{—} | Current sensor | 1 |
| | | ACS758 | | |
| LM358DR | U2 | SOP8 | Op. Amplifier | 1 |
| LM7805MP | VR1 | SOT23 | Linear regulator | 1 |

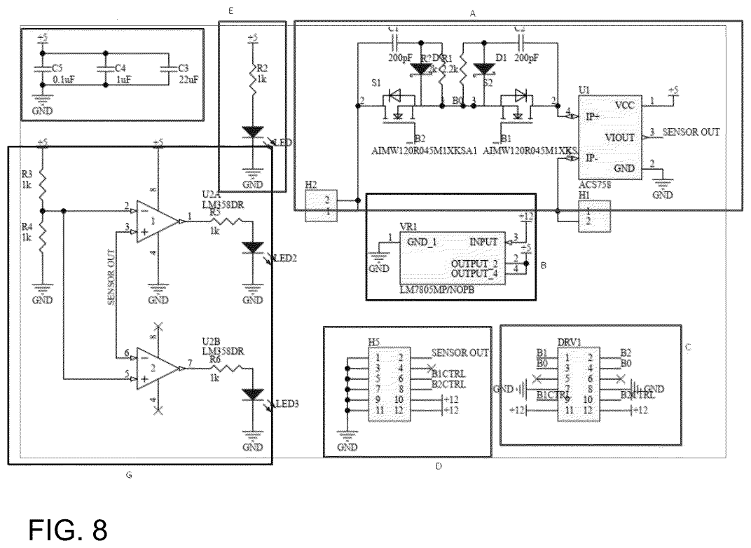

FIG. 8 illustrates the various sub-circuits shown in FIG. 7 with boxes around the sub-circuits used for identification purposes. Box A—This is the main part of the bidirectional switch. It contains 2 switching MOSFETs back-to-back along with the dual resistor capacitor diode snubber circuits and the current sensor (U1). H2 maps to port A, and H1 maps to port B in FIG. 4. Box B—This is a voltage regulator which gives a stable 5V supply from a 12V input for the current sensor in Box A and comparators in Box C. Box C—This is a pin header where a control circuit (as labeled in FIG. 4) would be plugged in. It is not necessary for the gate control circuit to be removable, but may be optionally used for an implementation. Box D—Pin header for power input (12V, current sensor output, and control signals for the gates of the two MOSFETS 43 and 44 (Sa and Sb in FIG. 4). Box E—Indicator LED, which is on when device is powered with 12V. Box F—Filter capacitors for the 5V power rail. These capacitors ensure the power line has low noise and is stable for the current sensor and comparator. Box G—Comparator circuit to provide a visual indication for which direction current is flowing. If SENSOR OUT is high (>2.5V), current is flowing from H2 to H1 and LED2 turns on while LED3 is off. If SENSOR OUT is low, <2.5V), LED3 is on while LED2 is off.

Below are descriptions of components depicted in FIGS. 7 and 8:
C3, C4, C5: power supply filter capacitors;
R3, R4: Form voltage divider which creates a reference voltage that the output of the current sensor is compared to (i.e., above this value, the current is flowing forward, but below it is going backwards);
R5, R6: Current limiting resistors for current direction indicator LEDs;
LED2, LED3: Current direction indicator LEDs;
R2: Current limiting resistor for power indicator LED;
U2: Dual op-amp which is used as a comparator for current direction indicator LEDs;
LED1: Power indicator LED;
H2,H1: Input and output terminals for the power line which the bidirectional switch controls;
C1,C2: Snubber circuit capacitors;
D1,D2: Snubber circuit diodes;
R1a,R1b: Snubber circuit resistors;
U1: Current sensor;
VR1: Voltage regulator providing power to current sensor, comparators, power indicator LED; and
H5: pin header for input power and control signals for bidirectional switch, output of current sensor.

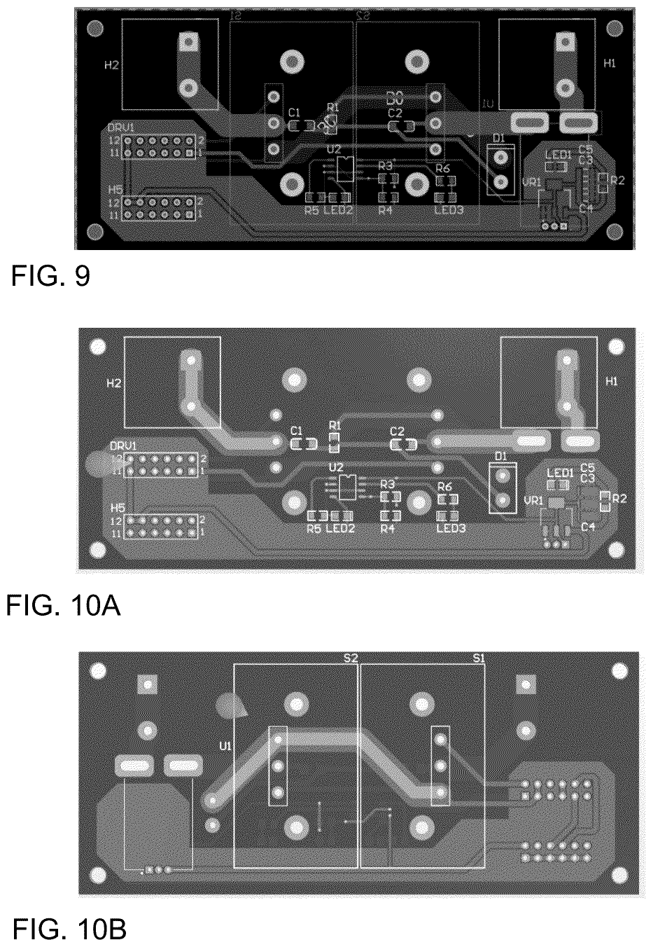

FIG. 9 is a contrast diagram for an embodiment of a circuit board for the circuits illustrated in FIGS. 7 and 8.

FIGS. 10A and 10B are a top-side view (FIG. 10A) and a bottom-side view (FIG. 10B) of the circuits of FIGS. 7, 8, and 9.

In one embodiment, to use this bidirectional solid-state relay safely, the operator should clear or verify with the system configuration if directional control of the current needs to be implemented. Noting that control signal Sₐ controls current from terminal A to terminal B. S_{b} controls current from terminal B to terminal A. If the solid-state relay 40 only works as full switch, use jumper on the device to short the input terminals (i.e., signals) and input only one control signal to close or open the solid-state relay 40. (Different voltage level signals for Sₐ and S_{b} should not be input if the jumper is connected to prevent potential damage to the control devices). The current sensor in the solid-state relay 40 can indicate the current direction for monitoring convenience.

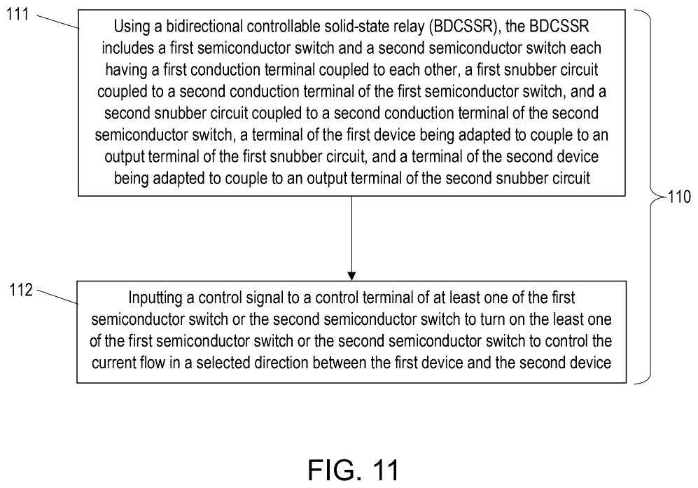

FIG. 11 is a flow chart for a method 110 for controlling an electrical current flow between a first device and a second device. Block 111 calls for using a bidirectional controllable solid-state relay (BDCSSR), the BDCSSR includes a first semiconductor switch and a second semiconductor switch each having a same-type terminal coupled to each other, a first snubber circuit coupled to an conduction terminal of the first semiconductor switch, and a second snubber circuit coupled to an conduction terminal of the second semiconductor switch, a terminal of the first device being adapted to couple to an output terminal of the first snubber circuit and a terminal of the second electrical device being adapted to couple to an output terminal of the second snubber circuit. In one or more embodiments, the first device is an electrical source and the second device is an electrical receiver. The term “electrical source” is intended to be inclusive of at least one of an electrical power source or an electrical signal source. The term “electrical receiver” is intended to be inclusive of at least one of an electrical load that receives electrical power or an electrical signal receiver. In one or more embodiments, the first and second semiconductor switches are MOSFETs and the conduction terminal is a source terminal. In one or more embodiments having MOSFETs, the first and second snubber circuits are coupled to a drain terminal of the respective MOSFET. In one or more embodiments, each of the first and second snubber circuits is a resistor-capacitor-diode (RCD) absorber circuit.

Block 112 calls for inputting a control signal to a control terminal of at least one of the first semiconductor switch or the second semiconductor switch to turn on the least one of the first semiconductor switch or the second semiconductor switch to control the current flow in a selected direction between the first device and the second device. In one or more embodiments, the control signal is input to both the first and second semiconductor switches to allow current flow from the first device to the second device and from the second device to the first device. In one or more embodiments, the control signal is input to only one of the first semiconductor switch and the second semiconductor switch to only allow current flow from either the first device to the second device or from the second device to the first device, respectively. In one or more embodiments, if no control signal is input to any of the semiconductor switches, then current will not flow in any direction. In one or more embodiments having MOSFETs, the control signal is input to a gate (G) terminal of the MOSFETs. The term “control terminal” relates to a terminal of the semiconductor switch that upon receiving an input signal will turn the semiconductor switch on (or alternatively turn the semiconductor device off if it is normally on). The term “conduction terminal” relates to a terminal of the semiconductor switch that will conduct current in response to the semiconductor switch being turned on.

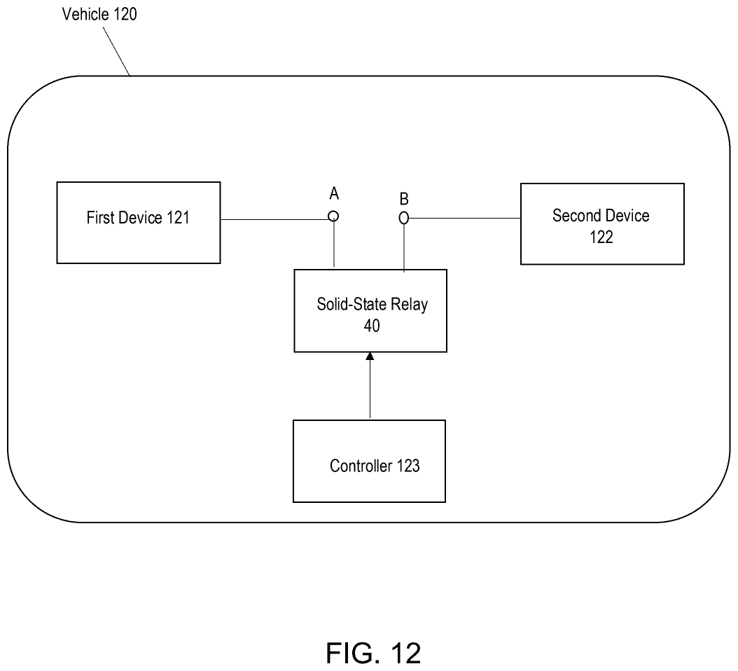

FIG. 12 illustrates a vehicle 120 having the solid-state relay 40. The solid-state relay 40 controls electrical current flow in a selected direction between a first device 121 (e.g., a battery) and a second device 122 (e.g., an electric motor). A controller 123 is coupled to the solid-state relay 40 and provides a control signal for controlling the direction of current flow. In one or more embodiments, the control signal is an application of voltage. The vehicle 120 is intended to represent any of the vehicles discussed further below.

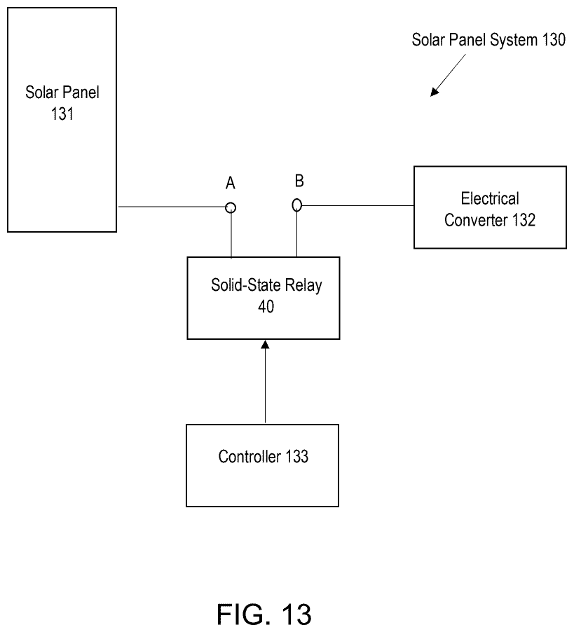

FIG. 13 illustrates a solar panel 130 coupled to the solid-state relay 40. The solid-state relay 40 controls electrical current flow between the solar panel 130 and an electrical converter 131. The electrical converter 131 is configured to convert power generated by the solar panel 130 to a type of electrical power suitable for home (e.g., 120-volt AC) or industrial use (e.g., 480-volt 3-phase AC). A controller 132 is coupled to the solid-state relay 40 and provides a control signal for controlling the current flow from the solar panel 130 to the electrical converter 131.

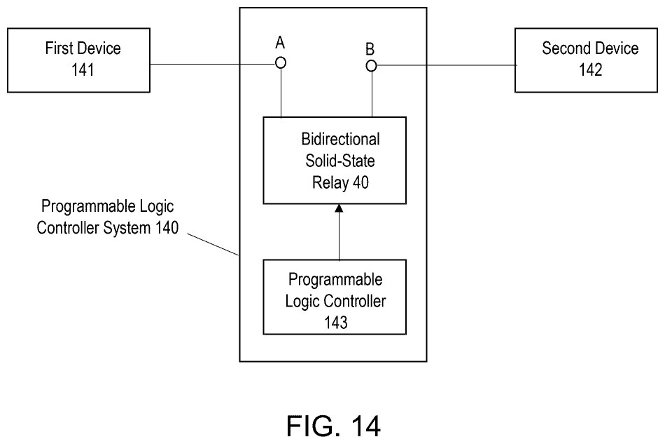

FIG. 14 illustrates a programmable logic controller system 140. The programmable logic controller system 140 includes the bidirectional solid-state relay 40 coupled to a first device 141 and a second device 142. The bidirectional solid-state relay 40 is configured to control electrical current flow between the first device 141 and the second device 142. A programmable controller 143 is coupled to and controls the bidirectional solid-state relay 40 according to programmed instructions stored on a non-transitory computer-readable medium. The programmed instructions when executed by a computer or processor control the flow of current at any selected time between the devices 141 and 142. The phrase “control the flow of current between the devices 141 and 142 at any selected time” relates to one of: (1) allow current flow only from the first device 141 to the second device 142; (2) allow current flow only from the second device 142 to the first device 141; (3) allow current flow in both directions between the first device 141 and the second device 142; and (4) do not allow current flow in any direction between the first device 141 and the second device 142.

The novel control solution for power line protection and control with the bidirectional controllable solid-state relay 40 provides a number of advantages over the prior art. The use of full soft switching achieves surge free performance for the solid-state relay 40. Other advantages include: (1) solid-state SiC MOSFETs have very fast response to an operation command; (2) the control SiC MOSFETs consumes less power compared to an electromagnetic relay; (3) current sensing provides the current monitoring for controllers with indicating LED to monitor intuitively; (4) independent control channel can configure the solid-state relay 40 to control current in a selected direction; and (5) the surge-free circuit protects the solid-state relay 40 from over-voltage/current damage, which improves reliability. These and other advantages may be realized depending on the application of the circuit.

Thus, provided herein is a soft-switched, efficient, and compact solid-state bidirectional switch that can be used in solid-state breakers, relays, and power electronics. The technology is unique in its high efficiency and therefore low temperature rise due to its soft switching, and its ability to be on, off, or modulated at high frequency. The technology enhances efficiency of solid-state switches, breakers, and switching power electronics circuits.

It may be recognized that the potential implementations of the teachings herein are substantial and diverse. Further, computer program products stored on non-transitory media may be provided for controlling circuits developed with technology according to this disclosure.

Non-limiting examples of diverse applications of the solid-state bidirectional switch include vehicles and especially vehicle subject to vibration such as marine vehicles (e.g., ships, boats, submarines), land vehicles (e.g., cars, campers, tractor/trailers, heavy vehicles), aircraft (e.g. piston-powered aircraft, jet-powered aircraft, fixed wing aircraft, rotary wing aircraft), and spacecraft. In vehicles powered by electricity (i.e., EVs), the solid-state bidirectional switch may be used for battery management systems. The examples also include switches in smart breaker panels for smart building or home applications. The examples further include solar energy applications such as microgrid reconfigurability that may include linking solar panels to energy storage or energy storage to loads. The examples further include industrial controls and automation (e.g., general replacement for relays in Programmable Logic Controller setups).

In support of the teachings herein, various analysis components may be used, including a digital and/or an analog system. For example, the controller 123, the controller 132, and/or the programmable logic controller 143 may include digital and/or analog systems. The system may have components such as a processor, storage media, memory, input, output, communications link (wired, wireless, optical or other), user interfaces (e.g., a display or printer), software programs, signal processors (digital or analog) and other such components (such as resistors, capacitors, inductors and others) to provide for operation and analyses of the apparatus and methods disclosed herein in any of several manners well-appreciated in the art. It is considered that these teachings may be, but need not be, implemented in conjunction with a set of computer executable instructions stored on a non-transitory computer readable medium, including memory (ROMs, RAMs), optical (CD-ROMs), or magnetic (disks, hard drives), or any other type that when executed causes a computer to implement the method of the present invention. These instructions may provide for equipment operation, control, data collection and analysis and other functions deemed relevant by a system designer, owner, user or other such personnel, in addition to the functions described in this disclosure.

All statements herein reciting principles, aspects, and embodiments of the disclosure, as well as specific examples thereof, are intended to encompass both structural and functional equivalents thereof. Additionally, it is intended that such equivalents include both currently known equivalents as well as equivalents developed in the future, i.e., any elements developed that perform the same function, regardless of structure.

Various other components may be included and called upon for providing for aspects of the teachings herein. For example, additional materials, combinations of materials and/or omission of materials may be used to provide for added embodiments that are within the scope of the teachings herein. Adequacy of any particular element for practice of the teachings herein is to be judged from the perspective of a designer, manufacturer, seller, user, system operator or other similarly interested party, and such limitations are to be perceived according to the standards of the interested party.

In the disclosure hereof any element expressed as a means for performing a specified function is intended to encompass any way of performing that function including, for example, a) a combination of circuit elements and associated hardware which perform that function or b) software in any form, including, therefore, firmware, microcode or the like as set forth herein, combined with appropriate circuitry for executing that software to perform the function. Applicants thus regard any means which can provide those functionalities as equivalent to those shown herein. No functional language used in claims appended herein is to be construed as invoking 35 U.S.C. § 112(f) interpretations as “means-plus-function” language unless specifically expressed as such by use of the words “means for” or “steps for” within the respective claim.

When introducing elements of the present invention or the embodiment(s) thereof, the articles “a,” “an,” and “the” are intended to mean that there are one or more of the elements. Similarly, the adjective “another,” when used to introduce an element, is intended to mean one or more elements. The terms “including” and “having” are intended to be inclusive such that there may be additional elements other than the listed elements. The term “exemplary” is not intended to be construed as a superlative example but merely one of many possible examples. The terms “first” and “second” and the like are used to distinguish items and do not denote a specific order. The term “coupled” relates to being coupled directly or indirectly using an intermediate device. The term “configured” relates one or more structural limitations of a device that are required for the device to perform the function or operation for which the device is configured.

The flow diagram depicted herein is just an example. There may be many variations to this diagram or the steps (or operations) described therein without departing from the scope of the invention. For example, operations may be performed in another order or other operations may be performed at certain points without changing the specific disclosed sequence of operations with respect to each other. All of these variations are considered a part of the claimed invention.

The disclosure illustratively disclosed herein may be practiced in the absence of any element which is not specifically disclosed herein.

While one or more embodiments have been shown and described, modifications and substitutions may be made thereto without departing from the scope of the invention. Accordingly, it is to be understood that the present invention has been described by way of illustrations and not limitation.

It will be recognized that the various components or technologies may provide certain necessary or beneficial functionality or features. Accordingly, these functions and features as may be needed in support of the appended claims and variations thereof, are recognized as being inherently included as a part of the teachings herein and a part of the invention disclosed.

While the invention has been described with reference to exemplary embodiments, it will be understood that various changes may be made and equivalents may be substituted for elements thereof without departing from the scope of the invention. In addition, many modifications will be appreciated to adapt a particular instrument, situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims.

What is claimed is:

1. An apparatus for controlling an electrical current flow between a first device and a second device, the apparatus comprising:
a first semiconductor switch comprising a first conduction terminal;
a second semiconductor switch comprising a first conduction terminal coupled to the first conduction terminal of the first semiconductor switch;
a first snubber circuit coupled to a second conduction terminal of the first semiconductor switch;
a second snubber circuit coupled to a second conduction terminal of the second semiconductor switch;
wherein the first snubber circuit is adapted to couple with the first device and the second snubber circuit is adapted to couple with the second device.

2. The apparatus according to claim 1, wherein each of the first semiconductor switch and the second semiconductor switch is a metal-oxide-semiconductor-field-effect-transistor (MOSFET).

3. The apparatus according to claim 1, wherein each of the first snubber circuit and the second snubber circuit comprises a resistor-capacitor-diode (RCD) network.

4. The apparatus according to claim 1, further comprising a control and drive circuit receptive to a first input signal for controlling the first semiconductor switch and a second input signal for controlling the second semiconductor switch, the control and drive circuit comprising a first output coupled to a control terminal of the first semiconductor switch and a second output coupled to a control terminal of the second semiconductor switch.

5. The apparatus according to claim 4, wherein the control and drive circuit further comprises a reference output coupled to the first conduction terminal of the first and second semiconductor switches, the reference output configured to provide a reference voltage.

6. The apparatus according to claim 1, wherein the apparatus is disposed in a vehicle.

7. The apparatus according to claim 1, wherein the apparatus is disposed in a solar panel system.

8. The apparatus according to claim 1, wherein the apparatus is disposed in a programmable logic controller system.

9. An apparatus comprising:
a first semiconductor switch having a first conduction terminal;
a second semiconductor switch having a first conduction terminal coupled to the first conduction terminal of the first semiconductor switch;
a first snubber circuit coupled to a second conduction terminal of the first semiconductor switch;
a second snubber circuit coupled to a second conduction terminal of the second semiconductor switch;
a first device coupled to an output terminal of the first snubber circuit; and
a second device coupled to an output terminal of the second snubber circuit.

10. The apparatus according to claim 9, wherein the first device comprises an electrical source and the second device comprises an electrical receiver.

11. The apparatus according to claim 10, wherein the electrical source comprises an electrical power source and the electrical receiver comprises an electrical load.

12. The apparatus according to claim 11, wherein the electrical power source comprises at least one of a battery or an electric generator and the electrical receiver comprises an electric motor-generator combination.

13. The apparatus according to claim 11, wherein the electrical power source comprises a solar panel and the electrical receiver comprises an electrical converter.

14. The apparatus according to claim 10, wherein the electrical source comprises a signal transmitter and the electrical receiver comprises an electrical signal receiver.

15. A non-transitory computer-readable medium comprising instructions for controlling an electrical current flow between a first device and a second device that when executed by a computer implements a method comprising:
operating a bidirectional controllable solid-state relay, the bidirectional controllable relay comprising: a first semiconductor switch having a first conduction terminal; a second semiconductor switch having a first conduction terminal coupled to the first conduction terminal of the first semiconductor switch; a first snubber circuit coupled to a second conduction terminal of the first semiconductor switch; a second snubber circuit coupled to a second conduction terminal of the second semiconductor switch; wherein the first device is coupled to an output terminal of the first snubber circuit and the second device is coupled to an output terminal of the second snubber circuit;
turning on the first semiconductor switch in response to the instructions allowing the electrical current flow from the first device to the second device;
turning on the second semiconductor switch in response to the instructions allowing the electrical current flow from the second device to the first device;
turning on the first semiconductor switch and the second semiconductor switch in response to the instructions allowing the electrical current flow from the first device to the second device and from the second device to the first device.
